(19) United States
(12) Patent Application Publication
(10) Pub. No.: US 2026/0059706 A1
(43) Pub. Date: Feb. 26, 2026

(54) COOLING DEVICE

(71) Applicant: NIDEC CORPORATION, Kyoto (JP)

(72) Inventors: Hiroki MORIOKA, Kyoto (JP); Masataka MATSUOKA, Kyoto (JP); Yu TACHIBANA, Kyoto (JP); Kenta GENTSU, Kyoto (JP)

(21) Appl. No.: 19/303,421

(22) Filed: Aug. 19, 2025

(30) Foreign Application Priority Data
Aug. 23, 2024 (JP) 2024-143398

(51) Int. Cl. H05K 7/20; G01M 3/16

(52) U.S. Cl. CPC H05K 7/20281; G01M 3/16; H05K 7/20254; H05K 7/20263; H05K 7/20272

(57) ABSTRACT

A cooling device includes a refrigerant circulator to perform heat exchange between a primary refrigerant and a secondary refrigerant and to cool an object to be cooled by circulating the secondary refrigerant, the refrigerant circulator including a first controller and a first connector connected to the first controller, a relay board on which a second controller, and a second connector and a plurality of third connectors connected to the second controller are mounted, a sensor connected to each of the plurality of third connectors, and a cable that connects the first connector and the second connector and includes a communication line. The second controller is configured or programmed to transmit information regarding detection by the sensor to the first controller via the communication line.

### CROSS-REFERENCE TO RELATED APPLICATIONS

The present invention claims priority under 35 U.S.C. § 119 to Japanese Patent Application No. 2024-143398, filed on Aug. 23, 2024, the entire contents of which are hereby incorporated herein by reference.

### 1. Field of the Invention

The present disclosure relates to cooling devices.

### 2. Background

Conventionally, there is known a technique for cooling an electronic device by supplying a refrigerant cooled by heat exchange by a heat exchanger to a cold plate. A leakage detection circuit that detects refrigerant leakage may be provided around the electronic device as described above.

In the case where leakage in a wider range is to be detected using the leakage detection circuit as described above, the wiring may be complicated.

### SUMMARY

A cooling device according to an example embodiment of the present disclosure includes a refrigerant circulator to perform heat exchange between a primary refrigerant and a secondary refrigerant, cool an object to be cooled by circulating the secondary refrigerant, the refrigerant circulator including a first controller and a first connector connected to the first controller, a relay board on which a second controller, and a second connector and a plurality of third connectors connected to the second controller are mounted, a sensor connected to each of the plurality of third connectors, and a cable to connect the first connector and the second connector and including a communication line. The second controller is configured or programmed to transmit information regarding detection by the sensor to the first controller via the communication line.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic diagram of a cooling system CS according to an example embodiment of the present disclosure.

FIG. 2A is a perspective view illustrating the inside of a CDU 100 according to an example embodiment of the present disclosure.

FIG. 2B is a plan view illustrating the inside of the CDU 100.

FIG. 3 is a diagram schematically illustrating a configuration of the rear side of the CDU 100.

FIG. 4 is a diagram schematically illustrating another exemplary configuration of the rear side of the CDU 100.

FIG. 5 is a diagram schematically illustrating an appearance of a repeater 200 according to an example embodiment of the present disclosure.

FIG. 6 is a circuit diagram illustrating connection between the CDU 100 and the repeater 200 in a sensor system SS.

FIG. 7 is a circuit diagram illustrating connection between the repeater 200 and a leak sensor 300 according to an example embodiment of the present disclosure.

FIG. 8 is a circuit diagram in a case where a single leak sensor 300 is connected to the CDU 100.

FIG. 9A is a schematic diagram illustrating a first example of a usage mode of the sensor system SS according to an example embodiment of the present disclosure.

FIG. 9B is a schematic diagram illustrating a second example of a usage mode of the sensor system SS according to an example embodiment of the present disclosure.

FIG. 9C is a schematic diagram illustrating a third example of a usage mode of the sensor system SS according to an example embodiment of the present disclosure.

FIG. 10 is a schematic diagram illustrating an example in which the CDU 100 and the repeater 200 are arranged in a server rack SR.

### DETAILED DESCRIPTION

Hereinafter, example embodiments of the present disclosure will be described with reference to the drawings.

In the present description, for easy understanding, a configuration and an arrangement position of each member will be described using an XYZ orthogonal coordinate system. In the following description, a direction along the X axis is called a first direction, a side on which an arrow of the X axis faces is called one side in the first direction, and the opposite side is called the other side in the first direction. A direction along the Y axis is called a second direction, a side on which an arrow of the Y axis faces is called one side in the second direction, and the opposite side is called the other side in the second direction. A direction along the Z axis is called a third direction, a side on which an arrow of the Z axis faces is called one side in the third direction, and the opposite side is called the other side in the third direction.

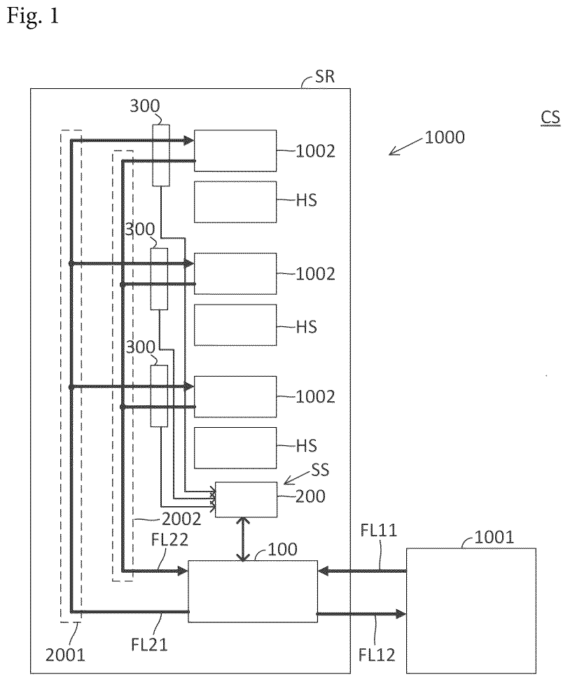

FIG. 1 is a schematic diagram of a cooling system CS according to an example embodiment. The cooling system CS includes a cooling device 1000 and a cooling unit 1001.

The cooling device 1000 cools a heat source HS. The heat source HS corresponds to an “object to be cooled”. For example, the heat source HS is, for example, a CPU of a rack mounted server, a blade server, or the like, and is disposed inside the server rack SR. In addition to the CPU, the heat source HS may be an electronic component such as an electrolytic capacitor, a power semiconductor module, or a printed circuit board. Furthermore, the heat source HS may be disposed inside an electronic device different from a server, such as a projector, a personal computer, or a display.

The cooling device 1000 includes a CDU 100. “CDU” is an abbreviation for “coolant distribution unit”. The CDU 100 corresponds to a “refrigerant circulator”. The CDU 100 is arranged inside the server rack SR. However, the present disclosure is not limited to this. The CDU 100 may be arranged outside the server rack SR.

The CDU 100 sucks a primary refrigerant to the inside of the CDU 100 and pumps the primary refrigerant to the outside of the CDU 100. The CDU 100 also sucks a secondary refrigerant to the inside of the CDU 100 and pumps the secondary refrigerant to the outside of the CDU 100. Since the inside of the CDU 100 is not provided with a pump on the primary refrigerant side, suction and pumping of the primary refrigerant in the CDU 100 are performed by an external pump. The CDU 100 performs heat exchange between the primary refrigerant and the secondary refrigerant. For example, refrigerant liquid such as antifreeze and pure water can be used as the primary refrigerant and the secondary refrigerant. Examples of the antifreeze usable as a refrigerant include an ethylene glycol aqueous solution and a propylene glycol aqueous solution. The primary refrigerant and the secondary refrigerant may be identical in type to each other or different in type from each other. At least one of the primary refrigerant and the secondary refrigerant may be a gas refrigerant.

The CDU 100 is connected to flow paths FL11 and FL12. The CDU 100 sucks the primary refrigerant flowing through the flow path FL11 and pumps the primary refrigerant to the flow path FL12. The CDU 100 is also connected to the flow paths FL21 and FL22. The CDU 100 pumps the secondary refrigerant to the flow path FL21 and sucks the secondary refrigerant flowing through the flow path FL22.

A low-temperature primary refrigerant flows into the CDU 100. A high-temperature secondary refrigerant also flows into the CDU 100. Inside the CDU 100, heat exchange is performed between the low-temperature primary refrigerant and the high-temperature secondary refrigerant. This cools the high-temperature secondary refrigerant.

The cooling unit 1001 cools the primary refrigerant. The cooling unit 1001 may be a device installed indoors or an outdoor facility such as a cooling tower. The cooling unit 1001 is connected to the flow path FL11. The cooling unit 1001 pumps the primary refrigerant to the CDU 100 via the flow path FL11. The cooling unit 1001 is also connected to the flow path FL12. The cooling unit 1001 sucks the primary refrigerant from the CDU 100 via the flow path FL12.

The cooling device 1000 includes a cold plate 1002. The cold plate 1002 is connected to the flow paths FL21 and FL22. The cold plate 1002 has an internal flow path. The internal flow path of the cold plate 1002 extends from a connection point with the flow path FL21 and reaches a connection point with the flow path FL22. That is, the secondary refrigerant is distributed inside the cold plate 1002.

The cold plate 1002 is in thermal contact with the heat source HS. The cold plate 1002 may be in direct contact with the heat source HS or may be in indirect contact with the heat source HS via a heat transfer member such as a heat transfer sheet.

When the cold plate 1002 and the heat source HS are in thermal contact with each other, thermal energy of the heat source HS is transferred to the secondary refrigerant distributed inside the cold plate 1002. As a result, the heat source HS is cooled. The secondary refrigerant used for cooling of the heat source HS flows into the CDU 100 via the flow path FL22.

The number of heat sources HS installed for the server rack SR is not particularly limited. The number of heat sources HS installed for the server rack SR may be plural or one.

When the number of heat sources HS installed for the server rack SR is plural, the same number (i.e., a plurality) of cold plates 1002 as the number of heat sources HS installed are installed in the server rack SR, and one cold plate 1002 may be in thermal contact with each heat source HS. In addition, a smaller number of cold plates 1002 than the number of heat sources HS installed may be installed in the server rack SR, and at least one of the cold plates 1002 may be in thermal contact with the plurality of heat sources HS.

When the number of the heat sources HS installed for the server rack SR is plural, for example, a part of the flow path FL21 is configured of a distribution manifold 2001, and a part of the flow path FL22 is configured of a collection manifold 2002.

The distribution manifold 2001 has one inflow port and a plurality of outflow ports. The secondary refrigerant flows into the inflow port of the distribution manifold 2001 from the CDU 100. The secondary refrigerant flowing in from the inflow port of the distribution manifold 2001 flows out from each outflow port of the distribution manifold 2001. The outflow ports of the distribution manifold 2001 are connected to the cold plates 1002 different from one another. Due to this, the secondary refrigerant flows into the cold plates 1002.

The collection manifold 2002 has a plurality of inflow ports and one outflow port. The inflow ports of the collection manifold 2002 are connected to the cold plates 1002 different from one another. The secondary refrigerant flowing out of each cold plate 1002 flows into the collection manifold 2002 via each inflow port of the collection manifold 2002. The outflow port of the collection manifold 2002 is connected to the CDU 100. Due to this, the secondary refrigerant flowing out of the cold plates 1002 flows into the CDU 100.

FIG. 1 shows a case where the number of cold plates 1002 installed (i.e., the number of heat sources HS installed) is three. In FIG. 1, a distribution direction of each refrigerant is indicated by an arrow orientation.

As described above, the cooling device 1000 includes the refrigerant circulator (100) that exchanges heat between the primary refrigerant and the secondary refrigerant, and circulates the secondary refrigerant to cool the object to be cooled.

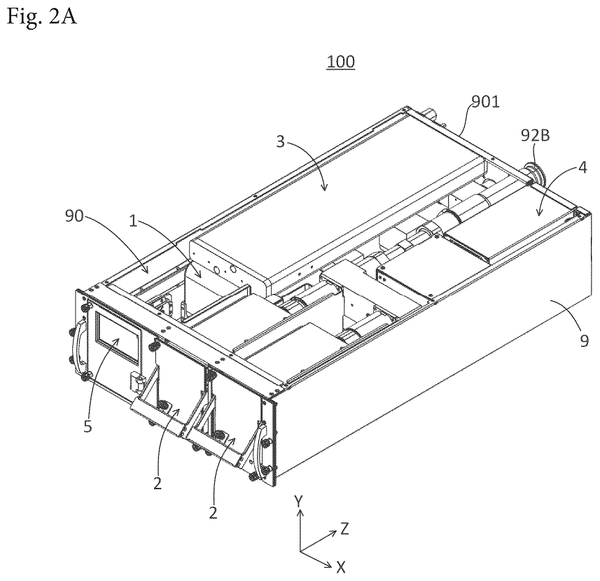

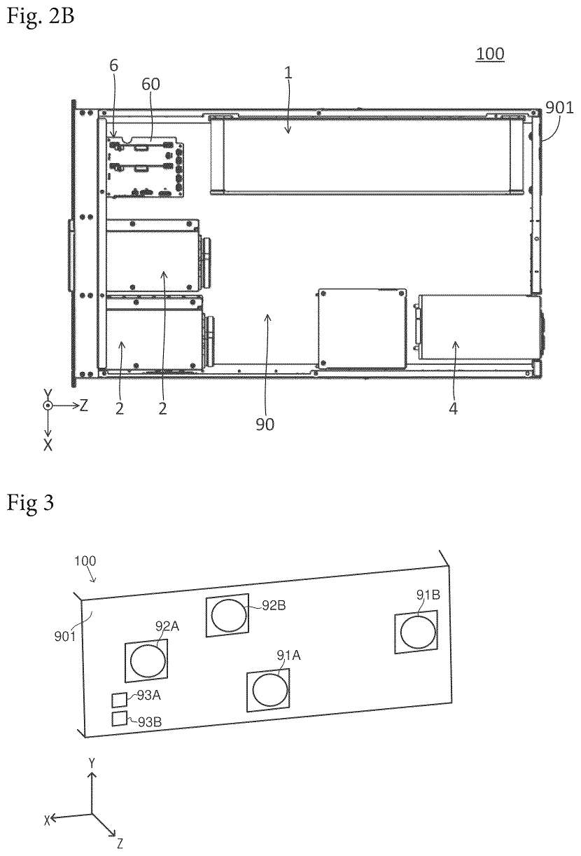

FIG. 2A is a perspective view illustrating the inside of the CDU 100 according to the example embodiment. The CDU 100 includes a housing 9. The housing 9 has an accommodation region 90. The housing 9 accommodates, in the accommodation region 90, a heat exchanger 1, a pump 2, a tank 3, a power supply unit 4, and a touchscreen 5. FIG. 2A illustrates a state in which the top surface of the housing 9 is removed.

FIG. 2B is a plan view illustrating the inside of the CDU 100. In FIG. 2B, illustration of some of the constituent members is omitted. As illustrated in FIG. 2B, a control board 6 is accommodated in the accommodation region 90.

The CDU 100 includes a primary flow path and a secondary flow path. The primary flow path and the secondary flow path are accommodated in the accommodation region 90. The primary flow path serves as a flow path for the primary refrigerant. The secondary flow path serves as a flow path for the secondary refrigerant.

The CDU 100 includes the heat exchanger 1. The heat exchanger 1 is connected to the primary flow path and the secondary flow path. The primary refrigerant and the secondary refrigerant flow into the heat exchanger 1 and flow out of the heat exchanger 1. The heat exchanger 1 exchanges heat between the primary refrigerant and the secondary refrigerant inside the heat exchanger 1. The heat exchange system of the heat exchanger 1 is a plate system, for example.

The CDU 100 includes the pump 2. The pump 2 is connected to the secondary flow path. The pump 2 has an internal flow path. When the pump 2 is driven, the secondary refrigerant is sucked into the internal flow path of the pump 2, and the secondary refrigerant is pumped from the internal flow path of the pump 2. Due to this, the secondary refrigerant circulates between the CDU 100 and the cold plate 1002. The number of pumps 2 installed is not particularly limited. For example, the number of pumps 2 installed is two. That is, the CDU 100 includes a plurality of pumps 2.

The CDU 100 includes the tank 3. The tank 3 stores a refrigerant used as the secondary refrigerant. The tank 3 is connected to the secondary flow path. The tank 3 can supply the refrigerant to the secondary flow path.

The CDU 100 includes the control board 6. A control circuit 60 is mounted on the control board 6. The control circuit 60 is connected to a temperature and humidity sensor that detects the temperature and humidity of the inside of the CDU 100, and is connected to a temperature sensor that detects the temperature of the primary refrigerant and a temperature sensor that detects the temperature of the secondary refrigerant. The control circuit 60 controls the pump 2 and the like. The control circuit 60 includes a circuit configuration such as a sensor microcomputer 601 described later. The sensor microcomputer 601 corresponds to a “first controller”.

The CDU 100 includes the power supply unit 4. The power supply unit 4 includes a power supply circuit. The power supply unit 4 is connected to a commercial power supply, and generates a direct-current voltage from an alternating-current voltage. The power supply unit 4 supplies electric power to a power-supplied unit that operates by receiving power supply, such as the pump 2, the control circuit 60, and various sensors.

The CDU 100 includes the touchscreen 5. The touchscreen 5 is connected to the control circuit 60. The control circuit 60 causes the touchscreen 5 to display various types of information. For example, the touchscreen 5 displays an operating status of the cooling system CS. The touchscreen 5 also displays measurement values of the temperature and humidity sensor and the temperature sensors. The touchscreen 5 is one of the power-supplied units that operate by receiving power supply from the power supply unit 4.

As illustrated in FIG. 1, the cooling device 1000 includes a sensor system SS for detecting leakage of a refrigerant, and the sensor system SS will be described in detail here. The sensor system SS includes the CDU 100, a repeater 200, and a leak sensor 300.

FIG. 3 is a diagram schematically illustrating a configuration of the rear side of the CDU 100. A back panel 901 shown in FIG. 3 is included in the housing 9. The back panel 901 is disposed on one side in the third direction.

The back panel 901 is provided with an inflow port 91A and an outflow port 91B. The inflow port 91A is connected to the primary flow path and serves as an inflow port of the primary refrigerant into the CDU 100. The outflow port 91B is connected to the primary flow path and serves as an outflow port of the primary refrigerant from the inside of the CDU 100.

The back panel 901 is provided with an inflow port 92A and an outflow port 92B. The inflow port 92A is connected to the secondary flow path and serves as an inflow port of the secondary refrigerant to the inside of the CDU 100. The outflow port 92B is connected to the secondary flow path and serves as an outflow port of the secondary refrigerant from the inside of the CDU 100.

The back panel 901 is provided with first connectors 93A and 93B. The first connectors 93A and 93B can be connected to the repeater 200 or the single leak sensor 300 described later. When the first connectors 93A and 93B are connected to the repeater 200, a cable 400 to be described later is used.

As illustrated in FIG. 3, on the rear surface of the refrigerant circulator (CDU 100), the first connectors 93A and 93B are disposed closer to the inflow port 91A and the outflow port 91B of the secondary refrigerant than the inflow port 92A and the outflow port 92B of the primary refrigerant in the first direction (X-axis direction) along the rear surface. As a result, the cable 400 can be installed along the pipe of the secondary refrigerant extending from the refrigerant circulator to the object to be cooled (heat source HS) side, and the workability of the cable installation is improved.

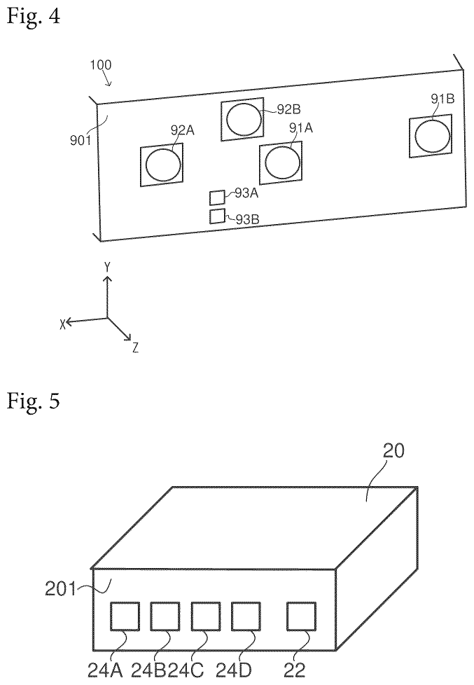

As illustrated in FIG. 3, on the rear surface of the refrigerant circulator (CDU 100), the first connectors 93A and 93B are disposed outside the inflow port 91A and the outflow port 91B of the primary refrigerant and the inflow port 92A and the outflow port 92B of the secondary refrigerant in the first direction (X-axis direction) along the rear surface. As illustrated in FIG. 4, the first connectors 93A and 93B may be disposed outside the inflow port 91A and the outflow port 91B of the primary refrigerant and the inflow port 92A and the outflow port 92B of the secondary refrigerant in the second direction (Y-axis direction) orthogonal to the first direction and along the rear surface. As a result, the cable 400 is easily attached to and detached from the first connector, and wiring work and maintenance are facilitated.

As illustrated in FIG. 3, the first connectors 93A and 93B are provided at ends on one side in the first direction and the other side in the second direction on the back panel 901. As can be seen from the configuration illustrated in FIG. 2A, on the rear surface of the refrigerant circulator (CDU 100), the first connectors 93A and 93B are disposed at positions not overlapping the heat exchanger 1 that performs heat exchange as viewed in a direction (third direction) perpendicular to the rear surface. This facilitates wiring between the first connectors 93A and 93B and the first controller (sensor microcomputer 601) in the refrigerant circulator. In addition, a space for wiring becomes unnecessary, and the size of the heat exchanger 1 can be increased.

FIG. 5 is a diagram schematically illustrating the appearance of the repeater 200. The repeater 200 includes a housing 20, a relay board 21 (not illustrated in FIG. 5), a second connector 22, and third connectors 24A to 24D. The relay board 21 is accommodated in the housing 20. The third connectors 24A to 24D are provided on a back panel 201 of the housing 20 and mounted on the relay board 21.

The second connector 22 can be connected to the first connector 93A or 93B using the cable 400. Each of the third connectors 24A to 24D can be connected to each of the leak sensors 300 (each of 300A to 300D described later). The leak sensor 300 is not necessarily connected to all of the third connectors 24A to 24D, and the leak sensor 300 may be connected to some of the third connectors 24A to 24D. For example, in the configuration of FIG. 1, three leak sensors 300 are used, and three of the third connectors 24A to 24D are used.

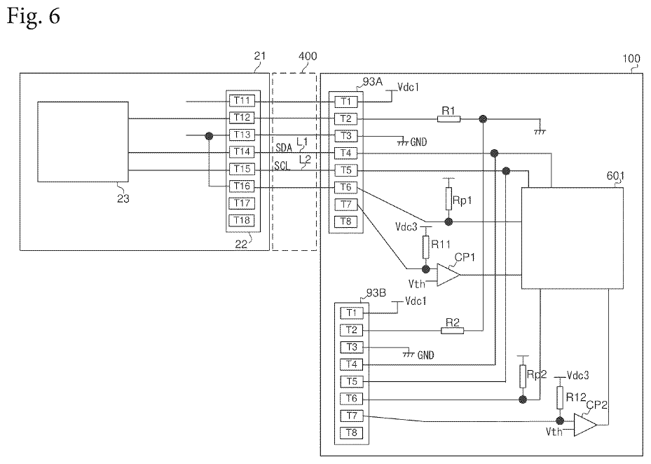

Next, a circuit configuration in the sensor system SS will be described. FIG. 6 is a circuit diagram illustrating connection between the CDU 100 and the repeater 200 in the sensor system SS. The CDU 100 and the repeater 200 are connected by the cable 400. The relay board 21 incorporated in the repeater 200 is illustrated in FIG. 6. Note that FIG. 6 illustrates a state in which the repeater 200 is connected to the first connector 93A, and another repeater 200 can be connected to the first connector 93B by another cable 400.

The first connectors 93A and 93B have the same configuration and each have pins T1 to T8. In the CDU 100, the sensor microcomputer 601, resistors R1 and R2, pull-up resistors Rp1 and Rp2, resistors R11 and R12, and comparators CP1 and CP2 are mounted on the control board 6.

The second connector 22 and an analog to digital (AD) converter IC 23 are mounted on the relay board 21. The AD converter IC 23 corresponds to a “second controller”. The second connector 22 includes pins T11 to T18.

The pin T1 is a power supply pin, and is connected to the application end of the DC voltage Vdc1. In the configuration of FIG. 6, the pin T1 is connected to the pin T11 by the cable 400. As a result, the DC voltage Vdc1 is supplied to the repeater 200 via the pin T11.

The pin T2 is an address setting pin. The pin T2 in the first connector 93A is connected to one end of the resistor R1, and the other end of the resistor R1 is connected to the application end of the ground potential. The pin T2 in the first connector 93B is connected to one end of the resistor R2, and the other end of the resistor R2 is connected to the other end of the resistor R1. In the configuration of FIG. 6, the pin T2 is connected to the pin T12 by the cable 400. The pin T12 is connected to the AD converter IC 23. An address setting method will be described later.

The pin T3 is a grounding pin, and is connected to the application end of the ground potential. In the configuration of FIG. 6, the pin T3 is connected to the pin T13 by the cable 400. As a result, the ground potential is supplied to the repeater 200 via the pin T13.

The pin T4 is a data terminal in inter-integrated circuit (I2C) communication, and is connected to the sensor microcomputer 601. I2C is one type of synchronous serial communication that performs data communication in synchronization with a clock. The pin T4 is connected to the pin T14 via a communication line L1 in cable 400. The pin T14 is connected to the AD converter IC 23. Thus, data SDA can be transmitted and received between the sensor microcomputer 601 and the AD converter IC 23 via the communication line L1. Note that the communication line L1 is pulled up.

The pin T5 is a clock terminal in the I2C communication, and is connected to the sensor microcomputer 601. The pin T5 is connected to the pin T15 via a communication line L2 in cable 400. The pin T15 is connected to the AD converter IC 23. Since the sensor microcomputer 601 is the master and the AD converter IC 23 is the slave in the I2C communication, a clock SCL is transmitted from the sensor microcomputer 601 to the AD converter IC 23 via the communication line L2. Note that the communication line L2 is pulled up.

As described above, the refrigerant circulator (100) includes the first controller (601) and the first connectors 93A and 93B connected to the first controller 601. The cooling device 1000 includes the second controller (23) and the relay board 21 on which the second connector 22 connected to the second controller is mounted. The cooling device 1000 also includes the cable 400 that connects the first connectors 93A and 93B and the second connector 22 and includes the communication lines L1 and L2.

The pin T6 is a connection detection pin. The pin T6 in the first connector 93A is connected to the sensor microcomputer 601 while being pulled up by the pull-up resistor Rp1. The pin T6 is connected to the pin T16 by the cable 400. The pin T16 is short-circuited with the pin T13. The pin T6 of the first connector 93B is connected to the sensor microcomputer 601 while being pulled up by the pull-up resistor Rp2. A connection detection method will be described later.

The pin T7 is a leakage voltage detection terminal. The pin T7 in the first connector 93A is connected to a first input terminal of the comparator CP1 while being connected to one end of the resistor R11. The other end of the resistor R11 is connected to the application terminal of the DC voltage Vdc3. A threshold voltage Vth is applied to a second input terminal of the comparator CP1. An output terminal of the comparator CP1 is connected to the sensor microcomputer 601. When the repeater 200 is connected to the first connector 93A as illustrated in FIG. 6, the pin T7 and the pin T17 are not connected. That is, the pin T7 is not used. The pin T7 in the first connector 93B is connected to a first input terminal of the comparator CP2 while being connected to one end of the resistor R12. The other end of the resistor R12 is connected to the application terminal of the DC voltage Vdc3. The threshold voltage Vth is applied to a second input terminal of the comparator CP2. An output terminal of the comparator CP2 is connected to the sensor microcomputer 601.

Pins T17, T8 and T18 are non-connected (NC) pins and are not used.

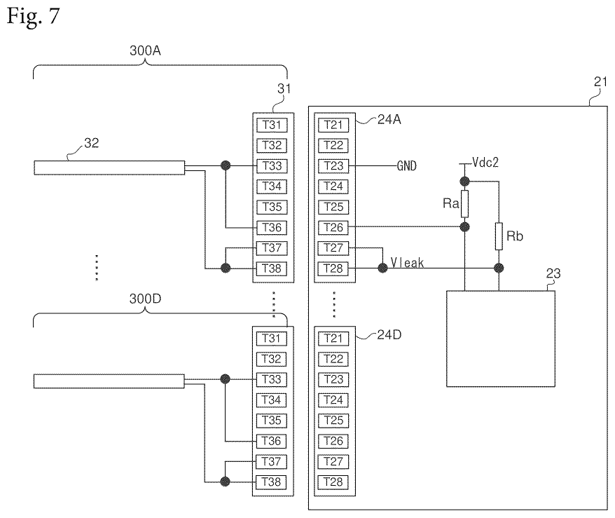

FIG. 7 is a circuit diagram illustrating connection between the repeater 200 and the leak sensor 300. In the repeater 200, the third connectors 24A to 24D and resistors Ra and Rb are mounted on the relay board 21. That is, the plurality of third connectors 24A to 24D are mounted on the relay board 21. Note that FIG. 7 illustrates a circuit configuration in which only the third connector 24A is mounted on the relay board 21, and the third connectors 24B to 24D are not illustrated, but a circuit similar to the third connector 24A is configured for each of the third connectors 24B to 24D.

Each of the third connectors 24A to 24D can be connected with each of the leak sensors 300A to 300D. That is, the cooling device 1000 includes sensors (300A to 300D) respectively connected to the plurality of third connectors 24A to 24D. The third connectors 24A to 24D have the same configuration and each have pins T21 to T28, respectively. The leak sensors 300A to 300D have the same configuration and each include a fourth connector 31 and a leakage detection unit 32.

The fourth connector 31 includes pins T31 to T38. By connecting the fourth connector 31 to any one of the third connectors 24A to 24D, the pins T31 to T38 are connected to the pins T21 to T28, respectively. The pin T23 is a grounding pin to which a ground potential is applied. Therefore, the ground potential is applied to the pin T33. The leakage detection unit 32 is connected between the pin T33 and the pins T37 and T38. The leakage detection unit 32 functions as a resistor. Pins T37 and T38 are short-circuited.

The pin T26 is a connection detection pin, and is connected to the AD converter IC 23 while being pulled up by the resistor Ra. The pin T36 is short-circuited with the pin T33. Therefore, when the fourth connector 31 of the leak sensor 300A is connected to the third connector 24A, the pin T26 of the third connector 24A becomes the low level, and the AD converter IC 23 can detect that the leak sensor 300A is connected to the third connector 24A. When no external connection is made to the third connector 24A, the pin T26 is set to the high level, and the AD converter IC 23 can detect that the not external connection is made to the third connector 24A. For the third connectors 24B to 24D, connection of each of the leak sensors 300B to 300D can be detected similarly.

The pins T27 and T28 are leakage voltage detection pins, are short-circuited, and are connected to the AD converter IC 23 while being connected to one end of the resistor Rb. The other end of the resistor Rb is connected to the application terminal of the DC voltage Vdc2. The DC voltage Vdc2 is generated on the basis of the DC voltage Vdc1 by a power supply circuit (not illustrated) mounted on the relay board 21.

When the fourth connector 31 is connected to any one of the third connectors 24A to 24D, the pin T37 is connected to the pin T27, and the pin T38 is connected to the pin T28. When the fourth connector 31 of the leak sensor 300A is connected to the third connector 24A, the resistor Rb and the leakage detection unit 32 are connected in series between the application terminal of the DC voltage Vdc2 and the application terminal of the ground potential via the pins T27, T28, T37, and T38 and the pins T33 and T23. Therefore, a leakage voltage Vleak obtained by dividing the DC voltage Vdc2 by the resistor Rb and the resistor of the leakage detection unit 32 is generated at the pins T27 and T28. When the leakage detection unit 32 is not wet, the resistance value of the resistor increases, and the leakage voltage Vleak increases. On the other hand, when the leakage detection unit 32 is wet due to liquid leakage, the resistance value of the resistor decreases, and the leakage voltage Vleak decreases. Therefore, the presence or absence of leakage can be detected by detecting the magnitude of the leakage voltage Vleak. Even when the leak sensors 300B to 300D are connected to the connectors 24B to 24D, leakage can be detected by each of the leak sensors 300B to 300D.

Next, address setting by the AD converter IC 23 will be described with reference to FIG. 6. As illustrated in FIG. 6, when the repeater 200 is connected to the first connector 93A, the AD converter IC 23 is connected to one end of the resistor R1 via the pins T12 and T2. On the other hand, when the repeater 200 is connected to the first connector 93B, the AD converter IC 23 is connected to one end of the resistor R2 via the pins T12 and T2. The resistance values of the resistors R1 and R2 are set to different values. Therefore, when the repeater 200 is connected to the first connector 93A or 93B, the AD converter IC 23 causes a constant pulsed current to flow to the pin T12, so that the pulsed voltage generated at the pin T12 has a different voltage value depending on the resistors R1 and R2. For example, when the resistance value of the resistor R1 is higher than that of the resistor R2, the voltage value of the pulsed voltage is higher when the repeater 200 is connected to the first connector 93A. The AD converter IC 23 sets its own address according to the voltage value generated at the pin T12. As a result, a different address is set in the AD converter IC 23 according to which of the first connectors 93A and 93B the repeater 200 is connected. The address is an address for the I2C communication.

That is, the refrigerant circulator (100) includes the plurality of first connectors 93A and 93B and the resistance elements R1 and R2 provided for each of the first connectors 93A and 93B. The second controller (23) is connectable to the resistance elements R1 and R2 via the second connector 22, the cable 400, and the first connectors 93A and 93B, and sets an address for communication by the communication lines L1 and L2 according to the resistance values of the resistance elements R1 and R2. As a result, the address can be set in each relay board 21 by connecting the relay board 21 to each of the plurality of first connectors 93A and 93B by the cable 400.

As illustrated in FIG. 6, when the repeater 200 is connected to the first connector 93A, the pin T6 is connected to the application terminal of the ground potential via the pins T16, T13, and T3. As a result, the pin T6 connected to one end of the pull-up resistor Rp1 becomes the low level, and the sensor microcomputer 601 can detect the external connection to the first connector 93A. On the other hand, when no external connection is made to the first connector 93A, the pin T6 is set to the high level by the pull-up of the pull-up resistor Rp1, and the sensor microcomputer 601 can detect that no external connection is made to the first connector 93A. Similarly, external connection can be detected for the first connector 93B.

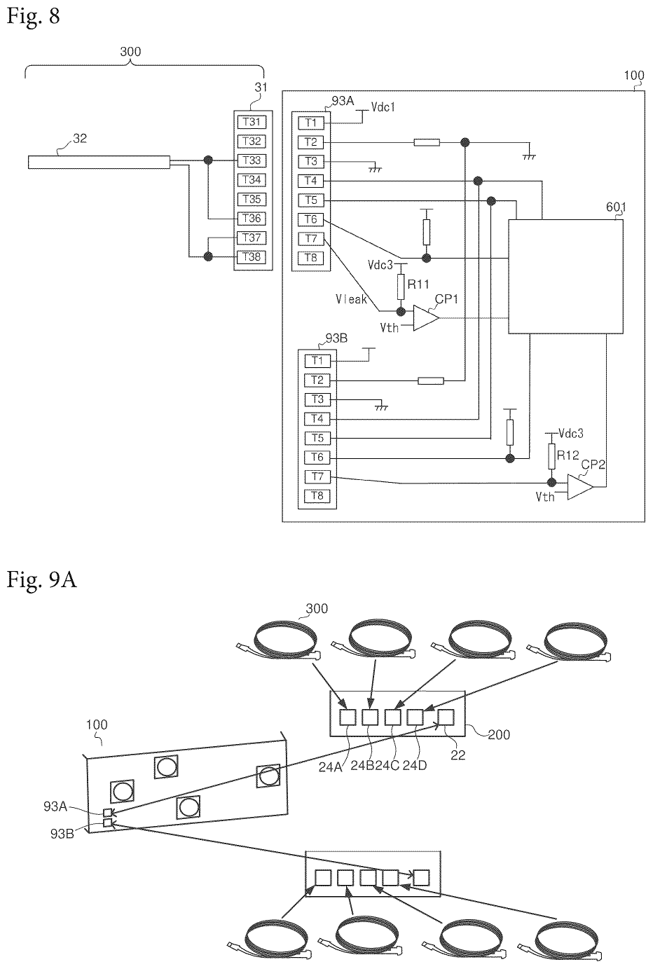

FIG. 8 is a circuit diagram in the case where a single leak sensor 300 is connected to the CDU 100. In the case of FIG. 8, the fourth connector 31 is connected to the first connector 93A. The fourth connector 31 may be connected to the first connector 93B. As illustrated in FIG. 8, when the fourth connector 31 is connected to the first connector 93A, the pins T6 and T36 and the pins T3 and T33 are connected respectively. As a result, the ground potential is applied to the pin T6. Therefore, the pin T6 connected to one end of the pull-up resistor Rp1 is at the low level, and the sensor microcomputer 601 can detect external connection to the first connector 93A. That is, it is possible to detect that the repeater 200 or the leak sensor 300 alone is externally connected by using the pin T6.

Next, an operation using the I2C communication will be described. When detecting that the sensor microcomputer 601 is externally connected to the first connector 93A by the pin T6, the sensor microcomputer 601 transmits an address that can be set in the AD converter IC 23 corresponding to the first connector 93A to the pin T4 using the data SDA by the I2C communication. Here, in the case where the repeater 200 is connected to the first connector 93A as illustrated in FIG. 6, the data SDA is transmitted to the AD converter IC 23 via the pins T4 and T14. Then, the AD converter IC 23 that has received the address returns an acknowledge (ACK) to the pin T14. As a result, the sensor microcomputer 601 receives the acknowledge via the pin T4 and detects that the repeater 200 is connected to the first connector 93A.

In the above case, the AD converter IC 23 subsequently transmits, to the sensor microcomputer 601 using the data SDA, data obtained by AD conversion of the leakage voltage Vleak detected by the leak sensor 300 connected to at least one of the third connectors 24A to 24D. Thus, the sensor microcomputer 601 can detect the presence or absence of leakage. That is, the second controller (23) transmits information (Vleak) regarding detection by the sensor (300) to the first controller (601) via the communication lines L1 and L2. As described above, according to the present example embodiment, a wide range can be detected by the plurality of sensors (300A to 300D), but by using the relay board 21, the wiring for the first controller (601) inside the refrigerant circulator (100) can be simplified.

When transmitting the data of the leakage voltage Vleak as described above, the AD converter IC 23 also transmits data for identifying which one of the leak sensors 300A to 300D is the leakage voltage Vleak using the data SDA. That is, the information regarding the detection by the sensor includes identification information capable of identifying by which sensor the detection has been made. As a result, the first controller (601) can identify by which sensor the detection has been made.

Similarly, when the repeater 200 is connected to the first connector 93B, the sensor microcomputer 601 transmits an address that can be set in the AD converter IC 23 corresponding to the first connector 93B to the pin T4 using the data SDA when detecting that external connection is made to the first connector 93B by the pin T6 of the first connector 93B. As a result, the sensor microcomputer 601 can acquire information regarding detection by the leak sensor 300 from the AD converter IC 23 after detecting that the repeater 200 is connected to the first connector 93B in response to the acknowledgment.

Moreover, when detecting that external connection is made to the first connector 93A by the pin T6, the sensor microcomputer 601 can detect that the leak sensor 300 alone is connected to the first connector 93A as illustrated in FIG. 8 when an address that can be set in the AD converter IC 23 corresponding to the first connector 93A is transmitted to the pin T4 using the data SDA and there is no reply of an acknowledgment. Since the pins T34 and T35 are non-connected pins, an acknowledgement is not returned. That is, when a signal is transmitted via the first connector 93A but a response (acknowledge) is not returned, the first controller (601) detects that a single sensor is connected to the first connector 93A. As a result, it is possible to detect that a single sensor is connected to the first connector 93A.

In the case where the single leak sensor 300 is connected to the first connector 93A as illustrated in FIG. 8, the sensor microcomputer 601 acquires an output of the comparator CP1 when detecting the connection of the single leak sensor 300. Since the first connector 93A and the fourth connector 31 are connected, the pins T7 and T37 and the pins T3 and T33 are connected, respectively. As a result, the resistor R11 and the resistor of the leakage detection unit 32 are connected in series between the application terminal of the DC voltage Vdc3 and the application terminal of the ground potential. Therefore, the comparator CP1 outputs a result obtained by comparing the leakage voltage Vleak generated at the pin T7 obtained by dividing the DC voltage Vdc3 by the resistor R11 and the resistor of the leakage detection unit 32 with the threshold voltage Vth. Thus, the sensor microcomputer 601 can detect the presence or absence of leakage.

Even when the leak sensor 300 is connected to the first connector 93B, the presence or absence of leakage can be detected based on the output of the comparator CP2 in the same manner as described above.

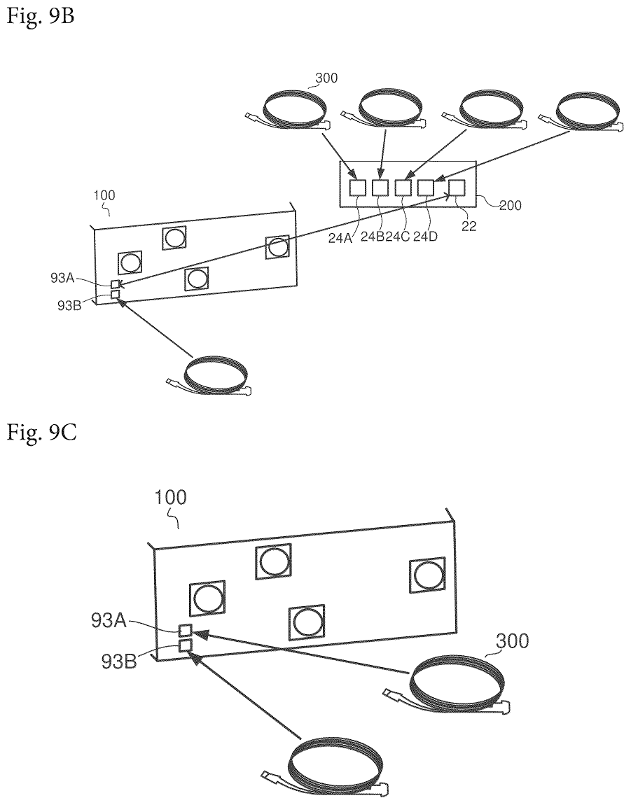

FIG. 9A is a schematic diagram illustrating a first example of a usage mode of the sensor system SS according to the present example embodiment. In this case, the repeater 200 is connected to each of the first connectors 93A and 93B. Four leak sensors 300 are connected to each repeater 200. Therefore, leakage in a wider range can be detected using eight leak sensors in total. Even when a large number of leak sensors 300 are used as described above, the wiring inside the CDU 100 is simplified by using the repeater 200.

FIG. 9B is a schematic diagram illustrating a second example of a usage mode of the sensor system SS according to the present example embodiment. In this case, the repeater 200 is connected to the first connector 93A, and the single leak sensor 300 is connected to the first connector 93B.

FIG. 9C is a schematic diagram illustrating a third example of a usage mode of the sensor system SS according to the present example embodiment. In this case, the single leak sensor 300 is connected to each of the first connectors 93A and 93B.

Even when the use mode is switched, the sensor microcomputer 601 can automatically detect the change of the use mode by the operation described above.

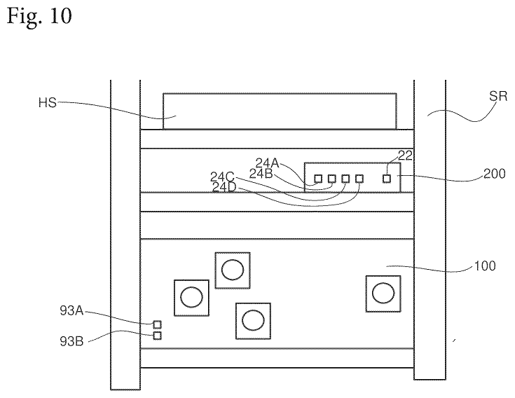

Here, the layout of the CDU 100 and the repeater 200 will be described. FIG. 10 is a schematic diagram illustrating an example in which the CDU 100 and the repeater 200 are arranged in the server rack SR. The CDU 100 is disposed at the lowermost stage of the server rack SR, the repeater 200 is disposed above the CDU 100, and the heat source HS is disposed above the repeater 200.

With such a layout, the leak sensor 300 (not illustrated in FIG. 10) in which one of the first connectors 93A and 93B is connected to the second connector 22 in the upper repeater 200 by the cable 400 (not illustrated in FIG. 10) and connected to one of the third connectors 24A to 24D in the repeater 200 is disposed on the heat source HS side. Therefore, the length of the leak sensor 300 can be shortened.

In the server rack SR, the CDU 100, the repeater 200, and the heat source HS may be arranged in order from the upper side. That is, the object to be cooled (HS) is disposed on one side of the upper side and the lower side of the refrigerant circulator (100), and the relay board 21 is disposed on the one side with respect to the first connectors 93A and 93B, so that the length of the sensor can be shortened.

Note that the length of the cable 400 is desirably longer than at least one of the plurality of sensors (300). As a result, the overall length of the cable 400 and the sensor can be shortened.

Here, the number of first connectors is desirably an even number like the first connectors 93A and 93B. In the case where the repeater is connected to each of the even-numbered first connectors, if the same portion is detected by the leak sensors 300 connected to a set of two repeaters, there is no problem even if one of the first connectors fails. Moreover, the number of third connectors is also desirably an even number like the third connectors 24A to 24D. As a result, if the same portion is detected by the leak sensor 300 connected to a set of two third connectors, there is no problem even if one of the third connectors fails. Therefore, redundancy can be provided by setting the number of first connectors or the number of third connectors to an even number.

The example embodiment of the present disclosure is described above. Note that the scope of the present disclosure is not limited to the above example embodiment. The present disclosure can be implemented by making various changes to the above example embodiment without departing from the gist of the disclosure. Further, the matters described in the above example embodiment can be optionally combined together, as appropriate, as long as there is no inconsistency.

For example, in the above example embodiment, the sensor is a liquid leakage sensor (leak sensor 300). This configuration enables detection of a refrigerant leak in a wide range. However, the sensor is not limited to a leak sensor, and may be, for example, a temperature sensor.

As described above, a cooling device according to the present disclosure includes a refrigerant circulator to perform heat exchange between a primary refrigerant and a secondary refrigerant and to cool an object to be cooled by circulating the secondary refrigerant, the refrigerant circulator including a first controller and a first connector connected to the first controller, a relay board on which a second controller, and a second connector and a plurality of third connectors connected to the second controller are mounted, a sensor connected to each of the plurality of third connectors, and a cable to connect the first connector and the second connector and includes a communication line. The second controller transmits information regarding detection by the sensor to the first controller via the communication line (first configuration).

In the first configuration, the cooling device may be configured such that the information regarding the detection by the sensor includes identification information enabling identification of which of the sensors made the detection (second configuration).

In the first or second configuration, the cooling device may be configured such that the first controller determines that a single sensor is connected to the first connector when a signal is transmitted via the first connector but a response (ACK) is not returned (third configuration).

In any one of the first to third configurations, the cooling device may be configured such that the refrigerant circulator includes a plurality of the first connectors and a resistance element provided for each of the plurality of first connectors, and that the second controller is connectable to the resistance element via the second connector, the cable, and the first connector, and sets an address for communication via the communication line according to a resistance value of the resistance element (fourth configuration).

In any one of the first to fourth configurations, the cooling device may be configured such that on a rear surface of the refrigerant circulator, the first connector is at a position closer to an inflow port and an outflow port of the secondary refrigerant than to an inflow port and an outflow port of the primary refrigerant in a first direction along the rear surface (fifth configuration).

In any one of the first to fifth configurations, the cooling device may be configured such that on a rear surface of the refrigerant circulator, the first connector is outside in a first direction along the rear surface or outside in a second direction orthogonal to the first direction and along the rear surface, with respect to an inflow port and an outflow port of the primary refrigerant and an inflow port and an outflow port of the secondary refrigerant (sixth configuration).

In any one of the first to sixth configurations, the cooling device may be configured such that on a rear surface of the refrigerant circulator, the first connector is at a position not overlapping a heat exchanger that performs the heat exchange when viewed from a direction perpendicular to the rear surface (seventh configuration).

In any one of the first to seventh configurations, the cooling device may be configured such that the object to be cooled is on one of an upper side and a lower side of the refrigerant circulator, and that the relay board is on the one side with respect to the first connector (eighth configuration).

In any one of the first to eighth configurations, the cooling device may be configured such that the length of the cable is longer than at least one of the plurality of sensors (ninth configuration).

In any one of the first to ninth configurations, the number of the first connectors or the number of the third connectors may be an even number (tenth configuration).

In any one of the first to tenth configurations, the cooling device may be configured such that the sensor is a liquid leakage sensor (eleventh configuration).

The present disclosure can be used for, for example, a cooling system for various purposes.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a refrigerant circulator to perform heat exchange between a primary refrigerant and a secondary refrigerant and to cool an object to be cooled by circulating the secondary refrigerant, the refrigerant circulator including a first controller and a first connector connected to the first controller;
a relay board on which a second controller, and a second connector and a plurality of third connectors connected to the second controller are mounted;
a sensor connected to each of the plurality of third connectors; and
a cable to connects the first connector and the second connector and includes a communication line; wherein
the second controller is configured or programmed to transmit information regarding detection by the sensor to the first controller via the communication line.

2. The cooling device according to claim 1, wherein the information regarding the detection by the sensor includes identification information enabling identification of which of the sensors made the detection.

3. The cooling device according to claim 1, wherein the first controller is configured or programmed to determine that a single sensor is connected to the first connector when a signal is transmitted via the first connector but a response is not returned.

4. The cooling device according to claim 1, wherein
the refrigerant circulator includes a plurality of the first connectors and a resistance element provided for each of the plurality of first connectors; and
the second controller is connectable to the resistance element via the second connector, the cable, and the first connector, and is configured or programmed to set an address for communication via the communication line according to a resistance value of the resistance element.

5. The cooling device according to claim 1, wherein on a rear surface of the refrigerant circulator, the first connector is at a position closer to an inflow port and an outflow port of the secondary refrigerant than to an inflow port and an outflow port of the primary refrigerant in a first direction along the rear surface.

6. The cooling device according to claim 1, wherein on a rear surface of the refrigerant circulator, the first connector is outside in a first direction along the rear surface or outside in a second direction orthogonal to the first direction and along the rear surface, with respect to an inflow port and an outflow port of the primary refrigerant and an inflow port and an outflow port of the secondary refrigerant.

7. The cooling device according to claim 1, wherein on a rear surface of the refrigerant circulator, the first connector is at a position not overlapping a heat exchanger that performs the heat exchange when viewed from a direction perpendicular to the rear surface.

8. The cooling device according to claim 1, wherein
the object to be cooled is on one of an upper side and a lower side of the refrigerant circulator; and
the relay board is on the one side with respect to the first connector.

9. The cooling device according to claim 1, wherein a length of the cable is longer than at least one of a plurality of the sensors.

10. The cooling device according to claim 1, wherein a number of the first connectors or a number of the third connectors is an even number.

11. The cooling device according to claim 1, wherein the sensor is a liquid leakage sensor.
